(19) United States
(12) Patent Application Publication
(10) Pub. No.: US 2006/0202306 A1
(43) Pub. Date: Sep. 14, 2006

(54) Bipolar junction transistor with high beta

(76) Inventors: Moshe Agam, Portland, OR (US); Richard Smoak, Beaverton, OR (US); Robert Bartel, Hillsboro, OR (US); Adrian McDonald, Bath (GB)

Correspondence Address: LATTICE SEMICONDUCTOR CORPORATION, 5555 NE MOORE COURT, HILLSBORO, OR, 97124-6421, US

(21) Appl. No.: 11/078,801

(22) Filed: Mar. 11, 2005

(51) Int. Cl. H01L 27/082

(52) U.S. Cl. 257/565

(57) ABSTRACT

In one embodiment of the invention, a bipolar junction transistor (BJT) includes an emitter comprised of a first doped region doped with a first dopant of a first conductivity type. In addition, a salicide block is disposed over a periphery portion of the first doped region, and a salicide is formed on an exposed portion of the first doped region inside the periphery portion. Such a salicide block prevents formation of salicide down to a base region in turn preventing leakage current through the base for increased β of the BJT.

### TECHNICAL FIELD

The present invention relates generally to bipolar junction transistors, and more particularly, to forming a bipolar junction transistor with a salicide block to increase beta.

### BACKGROUND

FIG. 1A shows a circuit symbol of a NPN BJT (bipolar junction transistor) 102 including a collector 104, a base 106, and an emitter 108. Referring to FIG. 1B, the NPN BJT 102 is formed when the collector 104 is a semiconductor material doped with an N-type dopant, the base 106 is a semiconductor material doped with a P-type dopant, and the emitter 108 is a semiconductor material that is doped with an N-type dopant.

FIG. 2A shows a circuit symbol of a PNP BJT (bipolar junction transistor) 112 including a collector 114, a base 116, and an emitter 118. Referring to FIG. 2B, the PNP BJT 112 is formed when the collector 114 is a semiconductor material doped with a P-type dopant, the base 116 is a semiconductor material doped with an N-type dopant, and the emitter 118 is a semiconductor material that is doped with a P-type dopant.

In either case, the BJT 102 or 112 amplifies current through the base (i.e., base current) to result in a current through the collector (i.e., collector current) that is beta (β) times the base current and in a current through the emitter (i.e., emitter current) that is (β+1) times the base current. Such current relations are expressed as follows:
I_{C}=β*I_{B}
I_{E}=(β+1)*I_{B}
with I_{B} being the base current, I_{C} being the collector current, and I_{E} being the emitter current. An important characteristic of the BJT is β, with a higher value of β resulting in better performance of an integrated circuit having the BJT.

FIG. 3 shows a cross-sectional view of a vertical PNP BJT 122 having a collector 124 formed with a P-type substrate, a base 126 formed with an N-type well, and an emitter 128 formed with a highly doped P-type region 128. A STI (shallow trench isolation) structure 130 surrounds and defines the area of the emitter 128.

In the prior art, for improving β of the vertical BJT 122, the N-type well 126 is doped with a lighter dopant concentration. Alternatively for improving β of the vertical BJT 122, the highly doped P-type region 128 and the N-type well 126 are formed to be deeper junctions. However, the lighter dopant concentration of the N-type well 126 disadvantageously results in degradation in electrical isolation between the highly doped P-type region 128 and the P-type substrate 124. In addition, the deeper junctions for the highly doped P-type region 128 and the N-type well 126 disadvantageously results in degradation of BJT roll-off characteristics.

Thus, a mechanism for increasing β of the BJT is desired without degrading other characteristics of the BJT.

### SUMMARY

In one embodiment of the invention, a bipolar junction transistor includes an emitter comprised of a first doped region doped with a first dopant of a first conductivity type. In addition, a salicide block is disposed over a periphery portion of the first doped region, and a salicide is formed on an exposed portion of the first doped region inside the periphery portion.

In another embodiment of the invention, a bipolar junction transistor further includes a base comprised of a second doped region that is doped with a second dopant of a second conductivity type that is opposite of the first conductivity type. The first doped region is formed on the second doped region. The bipolar junction transistor also includes a collector comprised of a third doped region doped with a third dopant of the first conductivity type and adjoining the second doped region.

### BRIEF DESCRIPTION OF THE DRAWINGS

FIG. 1A shows a circuit symbol of an NPN BJT (bipolar junction transistor), and FIG. 1B shows a typical cross sectional view of the NPN BJT of FIG. 1A, according to the prior art;

FIG. 2A shows a circuit symbol of a PNP BJT (bipolar junction transistor), and FIG. 2B shows a typical cross sectional view of the PNP BJT of FIG. 2A, according to the prior art;

FIG. 3 shows a cross-sectional view of a vertical PNP BJT, according to the prior art;

FIGS. 4, 5, 6, 7, 8, and 11 show cross-sectional views during fabrication of a PNP BJT with a salicide block for increasing β, according to an embodiment of the present invention;

FIGS. 9 and 10 show top views of the PNP BJT with the salicide block, according to an embodiment of the present invention;

FIG. 12 shows a cross-sectional view of a PNP BJT without a salicide block;

FIGS. 13 and 15 show a cross-sectional view of a NPN BJT with a salicide block for increasing β, according to an embodiment of the present invention;

FIG. 14 shows a top view of the NPN BJT with the salicide block, according to an embodiment of the present invention; and

FIG. 15 shows a circuit diagram of a band-gap voltage reference circuit using PNP BJTs with increased β, according to an embodiment of the present invention.

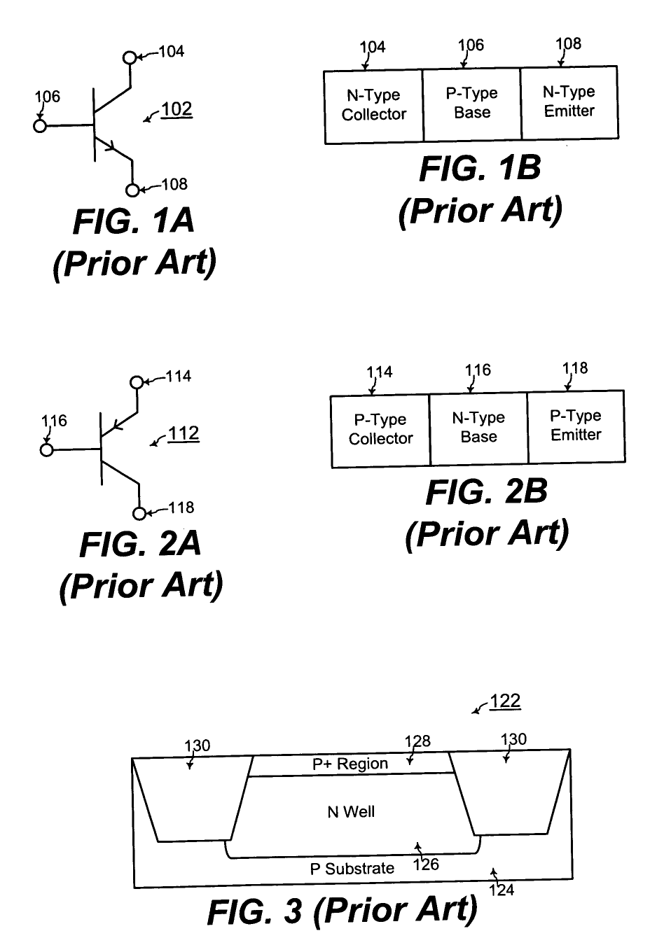

The figures referred to herein are drawn for clarity of illustration and are not necessarily drawn to scale. Elements in the figures having the same reference numerals refer to elements having similar structure and function.

### DETAILED DESCRIPTION

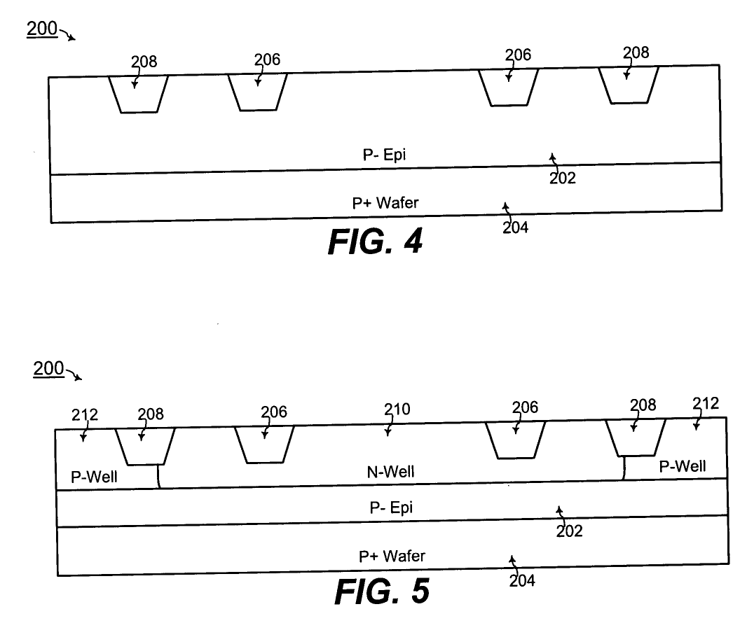

Referring now to the cross-sectional view of FIG. 4, a PNP BJT (bipolar junction transistor) 200 in one embodiment of the invention is formed in a P-type epitaxial layer 202 deposited on a P-type wafer 204. The P-type wafer 204 is doped with a P-type dopant with a dopant concentration of about 1×10²⁰. The P-type epitaxial layer 202 is doped with a P-type dopant with a lower dopant concentration of about 1×10¹⁵.

Typically, the wafer manufacturer provides the P-type epitaxial layer 202 deposited on the P-type wafer 204. The present invention may be generally practiced with forming the BJT in a general semiconductor substrate with the P-type epitaxial layer 202 being one example of the semiconductor substrate.

Further referring to FIG. 4, a first STI (shallow trench isolation) structure 206 and a second STI (shallow trench isolation) structure 208 are formed. The first and second STI structures 206 and 208 are comprised of a dielectric material such as silicon dioxide (SiO₂).

Referring to FIG. 5, after formation of the STI structures 206 and 208 an N-well 210 is formed in the P-type epitaxial layer 202 to be surrounded by the second STI structure 208. A P-well 212 is formed in the P-type epitaxial layer 202 to adjoin and surround the N-well 210. In one embodiment of the present invention, the N-well 210 and the P-well 212 are formed with implantation processes. Thus, an N-type dopant is implanted to form the N-well 210 with a dopant concentration of about 1×10¹⁶, and a P-type dopant is implanted to form the P-well 212 with a dopant concentration of about 1×10¹⁶.

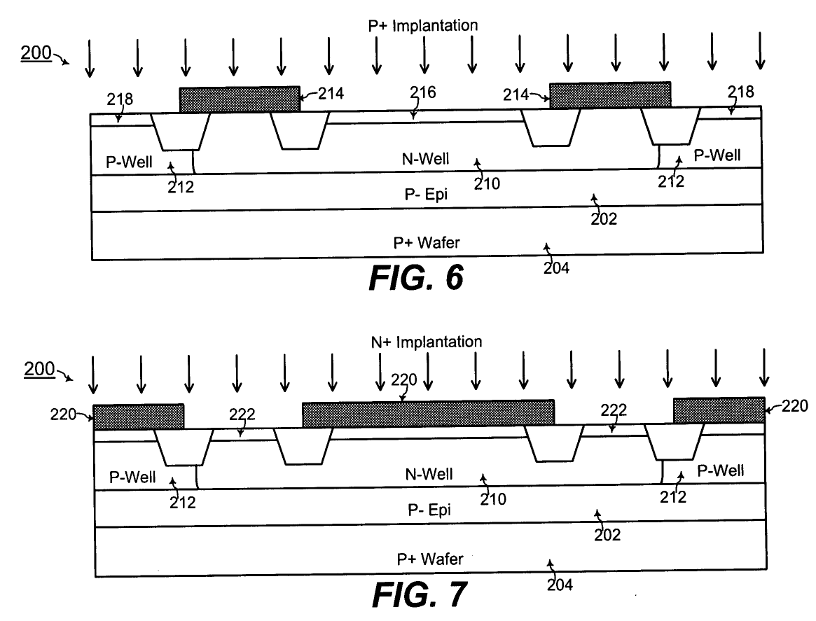

Referring to FIG. 6, after formation of the N-well 210 and the P-wells 212 a photo-resist mask 214 is formed over a portion of the N-well 210 between the STI structures 206 and 208. Thereafter, an implantation process is performed for implanting a P-type dopant to form a P+ highly doped region 216 on the exposed portion of N-well 210 between the STI structures 206. In addition, another P+ highly doped region 218 is formed on the exposed portion of the P-wells 212. For example, the P+ highly doped regions 216 and 218 are doped with a P-type dopant having a dopant concentration of about 1×10²⁰.

Referring to FIG. 7, after formation of the P+highly doped regions 216 and 218 the photo-resist mask 214 is removed and another photo-resist mask 220 is formed on the P+ highly doped regions 216 and 218. An implantation process is then performed for implanting an N-type dopant to form an N+ highly doped region 222 on the exposed portion of N-well 210 between the STI structures 206 and 208. The N+ highly doped region 222 has an N-type dopant concentration of about 1×10²⁰ in one embodiment of the present invention. In this manner, the vertical PNP BJT 200 is formed by the P+ highly doped region 216 forming the emitter, the N-well 210 forming the base, and the P-well 212 forming the collector.

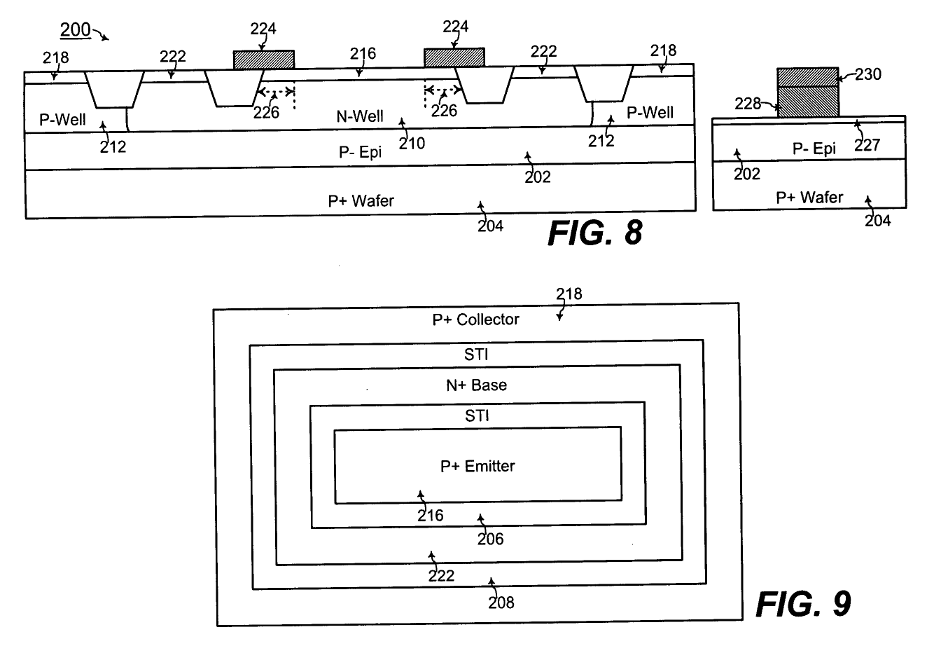

Referring to FIG. 8, after formation of the highly doped regions 216, 218, and 222 a salicide block 224 is formed over periphery portion 226 of the P+ highly doped region 216. Further referring to FIG. 8, in another portion of the semiconductor wafer 204, an insulating layer 227 is formed on the epitaxial layer 202, and a resistor structure 228 is formed on the insulating layer 227. The resistor structure 228 is comprised of polysilicon and is formed as a resistor of a CMOS (complementary metal oxide semiconductor) circuit for example. Another salicide block 230 is also formed on the resistor structure 228. In one embodiment of the present invention, the salicide blocks 224 and 230 are formed simultaneously.

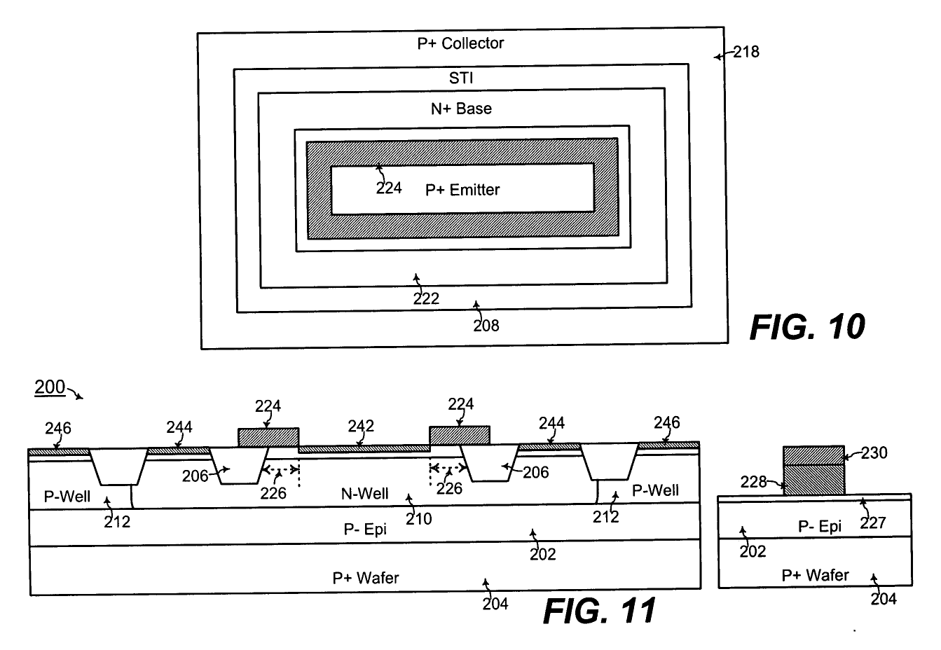

FIG. 9 shows a top view of the STI structures 206 and 208, the P+ highly doped region 218 for the collector, the P+highly doped region 216 for the emitter, and the N+ highly doped region 222 for the base, before formation of the salicide block 224. FIG. 10 shows the top view of FIG. 9 but after formation of the salicide block 224. Thus, FIG. 10 is the top view of the cross-sectional view of FIG. 8. The salicide blocks 224 and 230 are comprised of a dielectric material such as silicon dioxide (SiO₂) or silicon nitride (SiN) in one embodiment of the present invention.

Referring to FIG. 11, after formation of the salicide blocks 224 and 230 an emitter salicide 242 is formed on the exposed portion of the P+ highly doped region 216 for the emitter. Thus, the emitter salicide 242 is formed inside of the periphery portion 226 of the P+ highly doped region 216. In addition, a base salicide 244 is formed on the exposed portion of the N+ highly doped region 222 for the base. Furthermore, a collector salicide 246 is formed on the exposed portion of the P+highly doped region 218 for the collector.

The salicides 242, 244, and 246 are formed by depositing a metal onto the exposed regions 216, 222, and 218, respectively. Such metal reacts with the semiconductor material of the exposed regions 216, 222, and 218 to form the salicides 242, 244, and 246, respectively. Such salicides 242, 244, and 246 provide low resistance contact to the emitter, the base, and the collector, respectively, of the BJT 200.

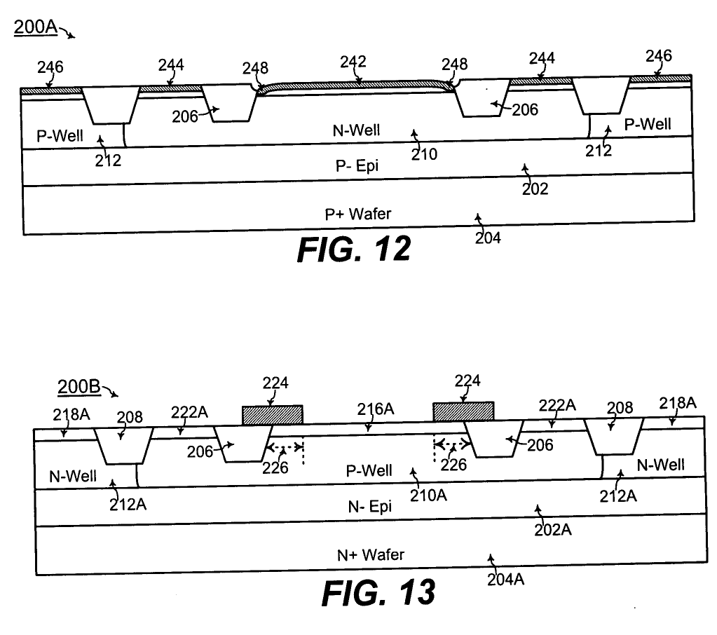

The salicide block 224 prevents formation of the emitter salicide 242 at the periphery portion 226 of the P+highly doped region 216 adjacent to the STI structure 206. FIG. 12 shows an alternative BJT 200A with formation of the emitter salicide 242 at the periphery portion 248 of the P+ highly doped region 216 adjacent the STI structure 206. In FIG. 12, no salicide block is formed at the periphery portion 248 of the P+ highly doped region 216. In that case, the periphery portion 248 of the P+ highly doped region 216 becomes rounded, and the emitter salicide 242 extends down toward the boundary between the P+ highly doped region 216 forming the emitter and the N-well 210 forming the base.

Such encroachment of the emitter salicide 242 toward the N-well 210 causes increased leakage current through the N-well 210 forming the base. The increased leakage current through the base 210 results in decreased β of the BJT 200A in FIG. 12. In contrast, in FIG. 11, the salicide block 224 in the periphery portion 226 prevents formation of the emitter salicide 242 at the periphery portion 226 such that the emitter salicide 242 does not extend down toward the boundary between the P+ highly doped region 216 forming the emitter and the N-well 210 forming the base. Thus, leakage current through the base 210 is minimized in the BJT 200 of FIG. 11 for maximizing β of the BJT 200 in FIG. 11.

Similarly, the salicide block 230 prevents formation of salicide on the polysilicon for the resistor 228 to maintain a high resistance of the resistor 228. In addition, the salicide block 224 is formed on the periphery portion 226 of the BJT 200 simultaneously with formation of the salicide block 230 such that another fabrication step is not added for formation of the salicide block 224.

FIG. 13 shows a cross-sectional view for an NPN BJT (bipolar junction transistor) 200B. The NPN BJT 200B is formed within an epitaxial layer 202A on a silicon wafer 204A including a P-well 210A that forms the base and an N-well 212A that forms the collector. The emitter is formed with an N+ highly doped region 216A. Another N+ highly doped region 218A is formed in the N-well 212A, and a P+ highly doped region 222A is formed in the P-well 210A. Thus, regions 202A, 204A, 210A, 212A, 216A, 218A, 222A of the NPN BJT 200B are similar to the regions 202, 204, 210, 212, 216, 218, 222, respectively of the PNP BJT 200 but with opposite conductivity of the respective dopant in each of such regions.

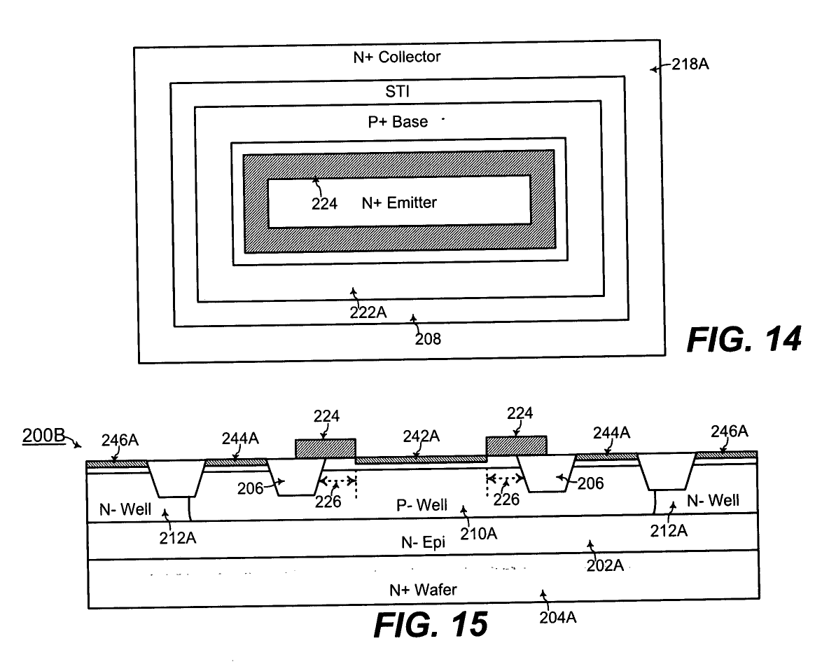

Further referring to FIG. 13, the salicide block 224 is also formed in the periphery portion 226 of the N+ highly doped region 216A. FIG. 14 shows a top view of the cross sectional view of FIG. 13 including the salicide block 224 formed in the periphery portion 226 of the N+ highly doped region 216A.

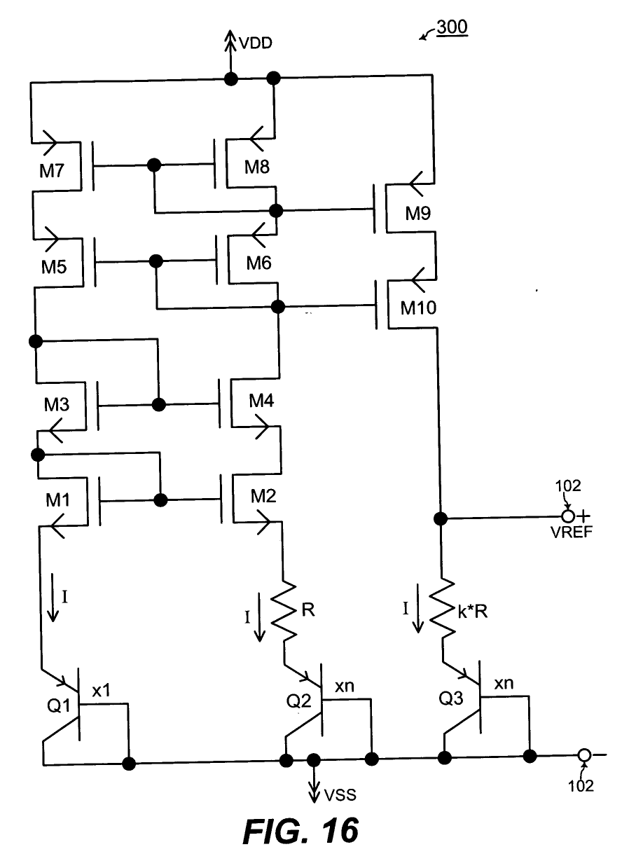

FIG. 15 shows formation of an emitter salicide 242A on the exposed portion of the N+ highly doped region 216A for the emitter. Thus, the emitter salicide 242A is formed inside of the periphery portion 226 of the N+ highly doped region 216A. In addition, a base salicide 244A is formed on the exposed portion of the P+ highly doped region 222A for the base. Furthermore, a collector salicide 246A is formed on the exposed portion of the N+ highly doped region 218A for the collector. Similar to the PNP BJT 200 of FIG. 11, the NPN BJT 200B of FIG. 15 has minimized leakage current through the base 210A to increase β of the BJT 200B of FIG. 15.

Such a BJT with increased β enhances the performance of an integrated circuit having the BJT incorporated therein. FIG. 16 shows a band-gap voltage reference circuit 300 having ten MOSFETs (metal oxide semiconductor field effect transistors) M1, M2, M3, M4, M5, M6, M7, M8, M9, and M10. In addition, the band-gap voltage reference circuit 300 includes three PNP BJTs Q1, Q2, and Q3 each having a respective base coupled to a respective collector at a low voltage source node VSS.

An emitter of the PNP BJT Q1 is coupled to a source of the MOSFET M1, an emitter of the PNP BJT Q2 is coupled to a source of the MOSFET M2 though a resistor with resistance value R, and an emitter of the PNP BJT Q3 is coupled to a drain of the MOSFET M10 through another resistor with resistance value k*R. The reference voltage VREF is generated across the drain of the MOSFET M10 and the low voltage source node VSS.

The sources of the MOSFETs M7, M8, and M9 are coupled to a high voltage source node VDD. In addition, the MOSFETs M1, M2, M3, M4, M5, M6, M7, M8, M9, and M10 are coupled to generate a same bias current level “I” through each of the PNP BJTs Q1, Q2, and Q3. With such bias, the voltages and currents through the PNP BJTs Q1, Q2, and Q3 are as follows:
VBE1=I*R+VBE2
I=(Vt/R)*ln(n)
VBE1 is a base to emitter voltage of the PNP BJT Q1, and VBE2 is a base to emitter voltage of the PNP BJT Q2. In addition, Vt is the thermal voltage kT/q with k being Boltzmann's constant, T being the temperature, and q being the electron charge. Furthermore, n is the ratio between an emitter area of a PNP BJT Q2 or Q3 to an emitter area of the PNP BJT Q1.

Thus, the reference voltage VREF may be expressed as follows:
VREF=−VBE3+I*(k*R)=k*Vt*In(n)−VBE3
VBE3 is a base to emitter voltage of the PNP BJT Q3. Thus, the constants k and n may be designed to minimize the temperature dependence of VREF by solving for the values of k and n when the derivative of VREF with respect to temperature is set to zero in the above equation for VREF. In one embodiment of the present invention, each of the three PNP BJTs Q1, Q2, and Q3 is formed with the salicide block 224 for increased β such that the performance of the band-gap voltage reference circuit 300 is enhanced.

The foregoing is by way of example only and is not intended to be limiting. For example, any materials or parameter values specified herein are by way of example only. Furthermore, any number or shape of elements as illustrated and described herein is by way of example only.

The present invention is limited only as defined in the following claims and equivalents thereof.

1. A bipolar junction transistor comprising:
an emitter comprised of a first doped region doped with a first dopant of a first conductivity type;
a salicide block disposed over a periphery portion of the first doped region; and
a salicide formed on an exposed portion of the first doped region inside the periphery portion.

2. The bipolar junction transistor of claim 1, further comprising:
a base comprised of a second doped region that is doped with a second dopant of a second conductivity type that is opposite of the first conductivity type, wherein the first doped region is formed on the second doped region.

3. The bipolar junction transistor of claim 2, further comprising:
a collector comprised of a third doped region doped with a third dopant of the first conductivity type and adjoining the second doped region.

4. The bipolar junction transistor of claim 3, further comprising:
a first highly doped region formed on the second doped region;
a base salicide formed on the first highly doped region;
a second highly doped region formed on the third doped region; and
a collector salicide formed on the second highly doped region.

5. The bipolar junction transistor of claim 4, further comprising:
a STI (shallow trench isolation) structure formed between the first and second highly doped regions.

6. The bipolar junction transistor of claim 3, wherein the second doped region is a first well formed into a semiconductor substrate, and wherein the first doped region is a highly doped region formed in the first well, and wherein the third doped region is a second well formed adjacent the first well.

7. The bipolar junction transistor of claim 6, wherein the bipolar junction transistor is a PNP type with the first well being of N-type for the base, the highly doped region being of P-type for the emitter, and the second well being of P-type for the collector.

8. The bipolar junction transistor of claim 6, wherein the bipolar junction transistor is an NPN type with the first well being of P-type for the base, the highly doped region being of N-type for the emitter, and the second well being of N-type for the collector.

9. The bipolar junction transistor of claim 2, wherein the second doped region is a first well formed into a semiconductor substrate, and wherein the first doped region is a highly doped region formed in the first well.

10. The bipolar junction transistor of claim 1, further comprising:
a STI (shallow trench isolation) structure that surrounds the first doped region.

11. The bipolar junction transistor of claim 1, wherein the salicide block is comprised of a dielectric material.

12. The bipolar junction transistor of claim 11, wherein the salicide block is comprised of one of silicon oxide (SiO₂) or silicon nitride (SiN).

13. The bipolar junction transistor of claim 1, wherein another portion of the salicide block is also formed on a resistor structure of a CMOS circuit.

14. The bipolar junction transistor of claim 1, wherein the bipolar junction transistor is formed as part of a band-gap reference circuit.

15. A bipolar junction transistor comprising:
an emitter comprised of a first doped region doped with a first dopant of a first conductivity type;
a base comprised of a second doped region that is doped with a second dopant of a second conductivity type that is opposite of the first conductivity type, wherein the first doped region is formed on the second doped region; and
means for reducing current between the first and second doped regions at an periphery portion of the second doped region.

16. The bipolar junction transistor of claim 15, further comprising:
a collector formed with a third doped region doped with a third dopant of the first conductivity type and adjoining the second doped region.

17. The bipolar junction transistor of claim 15, further comprising:
a STI (shallow trench isolation) structure that surrounds the first doped region.

18. A method for fabricating a bipolar junction transistor comprising:
forming a salicide block over a periphery portion of an emitter comprised of a first doped region doped with a first dopant of a first conductivity type; and
forming a salicide with an exposed portion of the first doped region inside the periphery portion.

19. The method of claim 18, further comprising:
forming a base comprised of a second doped region that is doped with a second dopant of a second conductivity type that is opposite of the first conductivity type, wherein the first doped region is formed on the second doped region; and
forming a collector comprised of a third doped region doped with a third dopant of the first conductivity type and adjoining the second doped region.

20. The method of claim 18, further comprising:
forming the salicide block simultaneously on the periphery portion of the emitter and on a resistor structure of a CMOS circuit.
